(19) United States
(12) Patent Application Publication
(10) Pub. No.: US 2017/0140900 A1
(43) Pub. Date: May 18, 2017

(54) UNIFORM LOW ELECTRON TEMPERATURE PLASMA SOURCE WITH REDUCED WAFER CHARGING AND INDEPENDENT CONTROL OVER RADICAL COMPOSITION

(71) Applicant: APPLIED MATERIALS, INC., Santa Clara, CA (US)

(72) Inventors: Leonid Dorf, San Jose, CA (US); Shahid Rauf, Pleasanton, CA (US); Vladimir Knyazik, Santa Clara, CA (US); Philip A. Kraus, San Jose, CA (US); Ying Zhang, Santa Clara, CA (US)

(21) Appl. No.: 14/940,539

(22) Filed: Nov. 13, 2015

(51) Int. Cl. H01J 37/32

(52) U.S. Cl. CPC H01J 37/32422; H01J 37/32357; H01J 37/3244; H01J 37/3211; H01J 37/32541; H01J 2237/334

(57) ABSTRACT

To generate a plasma for processing a workpiece, an electron beam is introduced into a plasma reactor chamber by radial injection using an annular electron beam source distributed around the circular periphery of the chamber to provide azimuthal uniformity. The electron beam propagation path is tilted upwardly away from the workpiece, either by tilting the electron beam source or by a magnetic field. In other embodiments, there are plural opposing electron beams from linear electron beam sources directed toward the center of the plasma reactor chamber.

### BACKGROUND

Technical Field

The disclosure concerns a plasma reactor for processing a workpiece such as a semiconductor wafer, the reactor including a uniform low electron temperature plasma source with reduced wafer charging and independent control over radical composition.

Background Discussion

Diminishing scale and increasing complexity of microfabrication process necessitate the use of novel ultra-sensitive materials, which in turn requires low-damage plasma etching with atomic layer precision. This imposes progressively stringent demands on accurate control over ion energy and radical composition during plasma processing. Using electron sheet beam (e-beam) parallel to the substrate surface to produce plasma in a processing chamber provides an order of magnitude reduction in electron temperature (about 0.3 eV) and ion energy (less than 2 eV without applied bias) compared to conventional plasma technologies, thus making electron beam plasmas an ideal candidate for processing features at 5 nm and below. Furthermore, since dissociation is performed only by high-energy beam and not plasma electrons, and the dissociation cross-section drops off considerably at beam energies of about 2 keV, the chemical composition of beam created plasma can be made radical-poor. This allows independent control over plasma radical composition, which is another advantage of using electron beam to create plasma.

Some of the critical challenges of developing an industry-worthy low electron temperature plasma source with independent control over radical composition include: (a) need for a uniform plasma distribution across the entire process region over the workpiece; (b) need for integration with a remote plasma source, which requires shielding of critical components from any magnetic fields required for electron beam source operation while preventing leakage of radicals from the e-beam source, which precludes the use of injection grids/apertures shared by remote source and e-beam source; and (c) need reduce workpiece charging by directing energetic beam electrons away from the workpiece to prevent surface charging and voltage build-up, which increases minimum ion energy at the workpiece.

### SUMMARY

A plasma reactor comprises: a processing chamber having a ceiling, a cylindrical side wall, a circumferential opening through the side wall and an axis of symmetry; and a workpiece support facing the ceiling. The plasma reactor further has an electron beam source comprising: a circularly distributed electron gun body surrounding the side wall and having an electron beam emission port coinciding with the circumferential opening and defining an electron beam path; a circularly distributed e-beam source filter grid in the electron beam emission port comprising plural elongate apertures parallel with the electron beam path, the electron gun body and the plural elongate apertures being tilted through a tilt angle relative to a radius of the axis of symmetry whereby the electron beam path is tilted in a direction away from the workpiece support; and a remote plasma source comprising a remote chamber overlying the ceiling and having an outlet facing the processing chamber, and a showerhead covering the outlet.

In one embodiment, the electron beam source further comprises: an emission electrode near an end of the electron gun body opposite the electron beam emission port; and, an RF power feed conductor coupled to the emission electrode.

The emission electrode may be tilted through the tilt angle. The processing chamber, the e-beam source filter grid, the electron gun body, the outlet and the workpiece support may be coaxial.

The plasma reactor may further comprise an RF bias power source coupled to the workpiece support.

The plasma reactor can further comprise first and second plasma RF source power supplies coupled to the external end of the RF power feed.

In one embodiment, the e-beam source filter grid comprises apertures of a first length and a first opening size, and the showerhead comprises apertures of a second length and a second opening size, the first length exceeding the second length and the first opening size exceeding the second opening size.

In one embodiment, the remote plasma source comprises a gas supply feed, a plasma source power applicator and a plasma source power supply coupled to the plasma source power applicator. The remote plasma source may include a radical production control.

The electron beam source may further comprise an electron beam source controller coupled to one of the first and second plasma RF source power supplies.

In accordance with a further aspect, a plasma reactor comprises: a processing chamber having a ceiling and an axis of symmetry; a workpiece support in facing the ceiling; an array of electron beam sources each having a respective electron beam path toward the axis of symmetry. Each one of the electron beam sources comprises: an electron gun body having an electron beam emission port coinciding with the respective electron beam path; an e-beam source filter grid in the electron beam emission port comprising plural elongate apertures parallel with the respective electron beam path, the electron gun body and the plural elongate apertures being tilted through a tilt angle relative to a radius of the axis of symmetry whereby the respective electron beam path is tilted in a direction away from the workpiece support. The reactor further comprises a remote plasma source comprising a remote chamber overlying the ceiling and having an outlet facing the processing chamber, and a showerhead covering the outlet.

In one embodiment, each of the electron beam sources further comprises: an emission electrode near an end of the electron gun body opposite the electron beam emission port; and, an RF power feed conductor coupled to the emission electrode.

In one embodiment, the emission electrode is tilted through the tilt angle.

In accordance with a further embodiment, a plasma reactor comprises: a processing chamber having a ceiling, a cylindrical side wall, a circumferential opening through the side wall and an axis of symmetry; a workpiece support facing the ceiling; and an electron beam source.

In this embodiment, the electron beam source comprises: a circularly distributed electron gun body surrounding the side wall and having an electron beam emission port coinciding with the circumferential opening; a circularly distributed e-beam source filter grid in the electron beam emission port; a magnet adjacent the electron gun body for diverting an electron beam flowing through the electron beam emission port to an electron beam path that is tilted away from a plane of the workpiece support through a tilt angle; and a remote plasma source comprising a remote chamber overlying the ceiling and having an outlet facing the processing chamber, and a showerhead covering the outlet.

In one embodiment, the electron beam source is axial and emits electrons in an axial direction.

In one embodiment, the electron beam source is radial and emits electrons in a radial direction.

In one embodiment, the electron beam source further comprises: an emission electrode near an end of the electron gun body opposite the electron beam emission port; and an RF power feed conductor coupled to the emission electrode.

### BRIEF DESCRIPTION OF THE DRAWINGS

So that the manner in which the exemplary embodiments of the present invention are attained can be understood in detail, a more particular description of the invention, briefly summarized above, may be had by reference to the embodiments thereof which are illustrated in the appended drawings. It is to be appreciated that certain well known processes are not discussed herein in order to not obscure the invention.

FIG. 1A is a cut-away elevational view of a plasma reactor of a first embodiment including a mechanically tilted cylindrical electron beam source.

FIG. 1B is a plan view corresponding to FIG. 1A.

FIG. 2A is a cut-away elevational view of a plasma reactor of a second embodiment including a symmetrical array of mechanically tilted electron beam sources.

FIG. 2B is a plan view corresponding to FIG. 2A.

FIG. 3A is a cut-away elevational view of a plasma reactor of a third embodiment including a cylindrical electron beam source with magnetic tilting.

FIG. 3B is a plan view corresponding to FIG. 3A.

FIG. 4A is a cut-away elevational view of a plasma reactor of a fourth embodiment including an axial electron beam source with magnetic tilting.

FIG. 4B is a plan view corresponding to FIG. 4A.

FIG. 5A is a cut-away elevational view of a plasma reactor of a fourth embodiment including a pair of opposing radial electron beam sources with magnetic tilting.

FIG. 5B is a plan view corresponding to FIG. 5A.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

### Introduction and Overview:

Embodiments described herein satisfy all of the foregoing criteria. An electron beam is introduced by radial injection using an annular beam source distributed around the circular periphery of the chamber to provide azimuthal uniformity. In a different embodiment, four planar electron beam sources at right angles provide at least a 4-fold symmetry, and remaining non-uniformities are expected to be compensated by diffusion. The electron beam is made to propagate at an angle relative to the workpiece surface.

Injecting the electron beam at an angle relative to the workpiece surface reduces charging of the workpiece. Distributing the beam source around the periphery of the chamber leaves room above the workpiece for accommodating a separate remote plasma source for supplying radicals to the processing chamber. The remote plasma source requires a showerhead at the interface to the processing chamber to allow only radicals to reach the workpiece from the remote plasma source, while blocking remote source-created plasma ions from entering the processing chamber. In the processing chamber, a special low-electron temperature plasma is created by the electron beam. Another separate grid (an e-beam source filter grid) is required to prevent the leakage of plasma by-products and radicals created inside the electron beam source into the processing chamber and to block chemically aggressive process gas from entering the electron beam source cavity from the processing chamber. The e-beam source filter grid is placed between the electron beam source and the processing chamber. The e-beam source filter grid, serves a purpose different from that of the showerhead of the remote plasma source: the e-beam source filter grid blocks the radicals produced inside the electron beam source but is transparent to high-energy electrons; while, the showerhead of the remote source admits radicals into the processing chamber. Therefore, in embodiments disclosed herein, the two grids are not shared and are physically separated.

In one embodiment, the showerhead of the remote plasma source can be made with a thinner plate and have smaller diameter holes than the e-beam source filter grid.

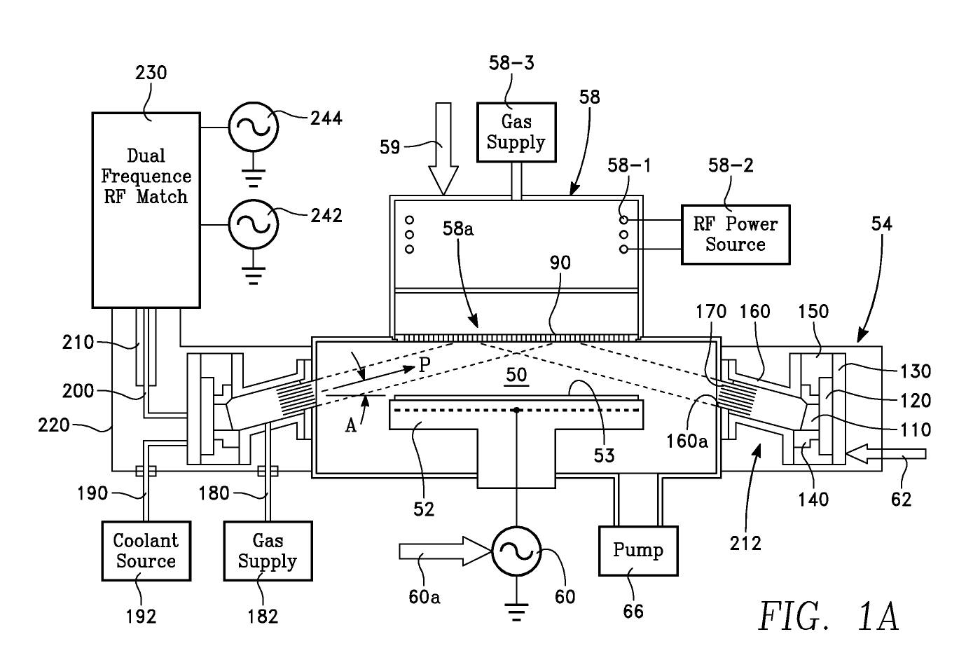

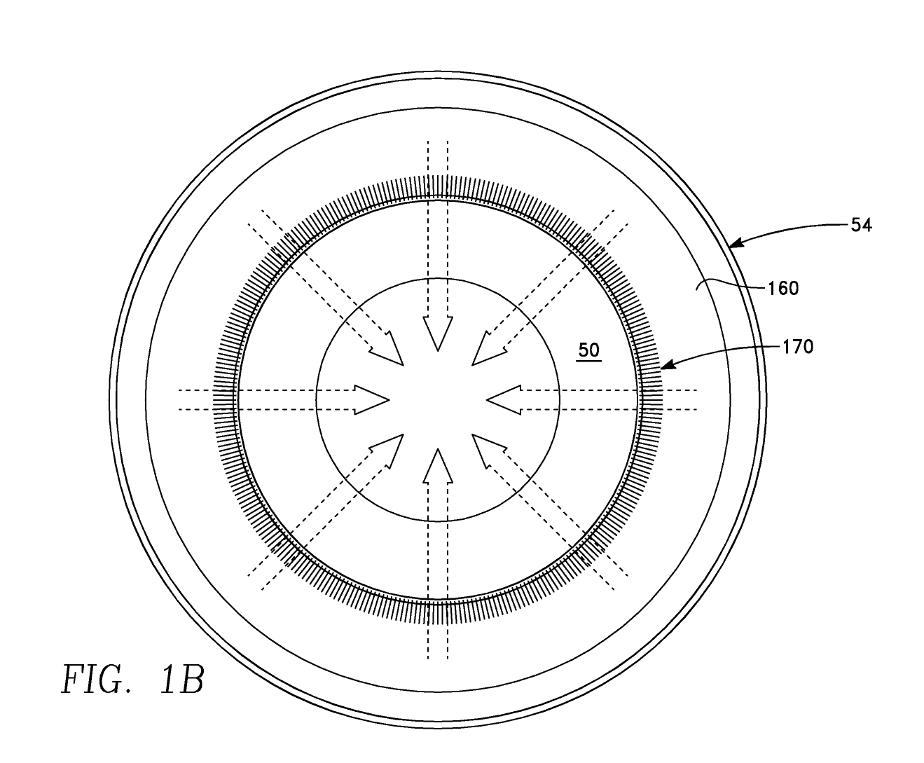

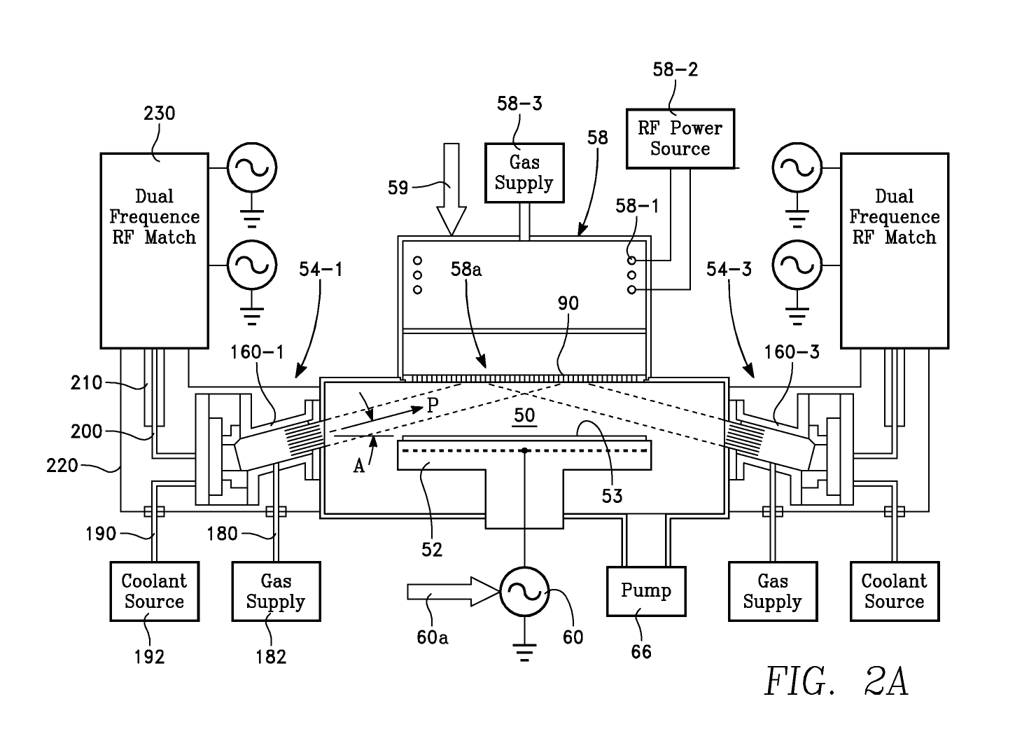

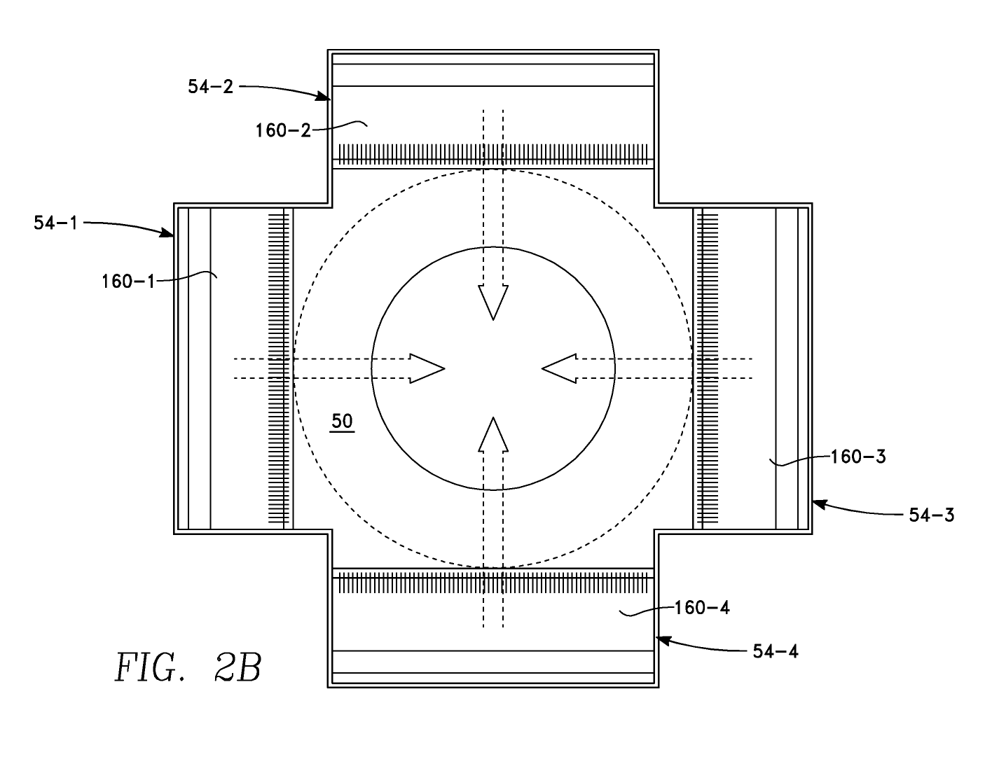

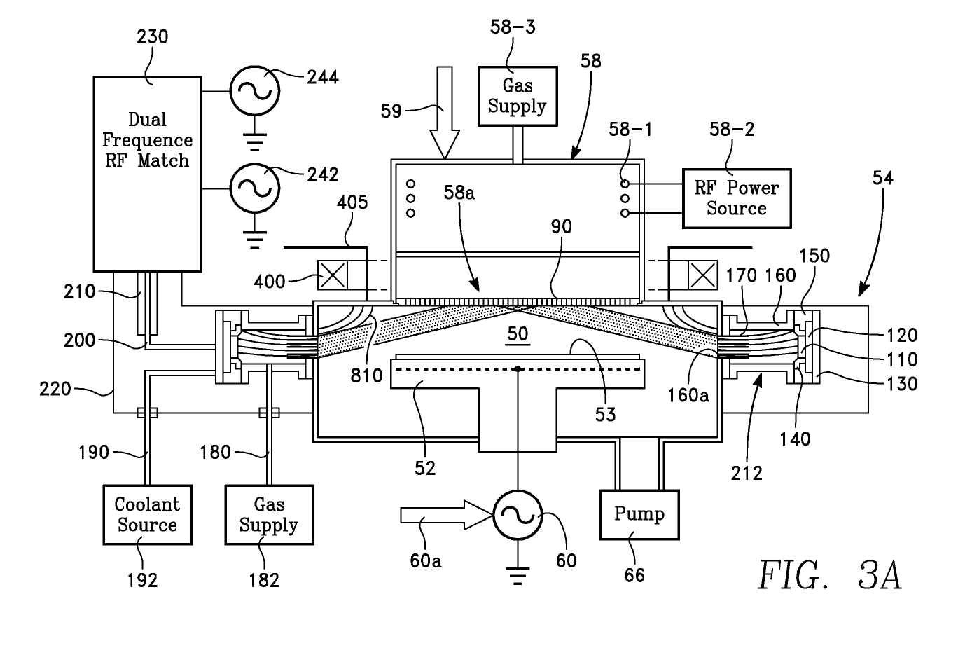

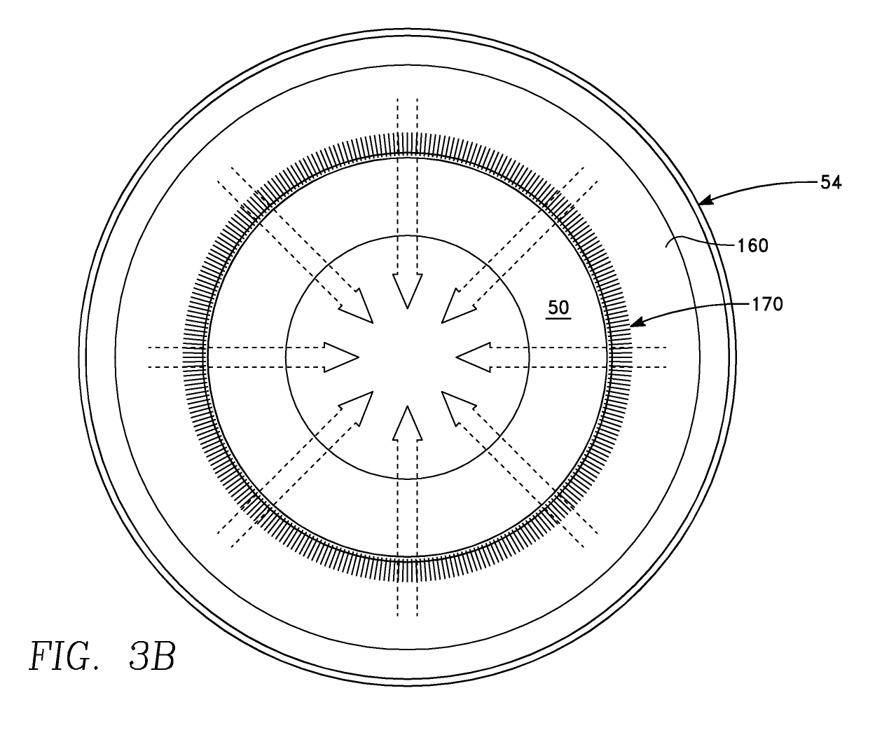

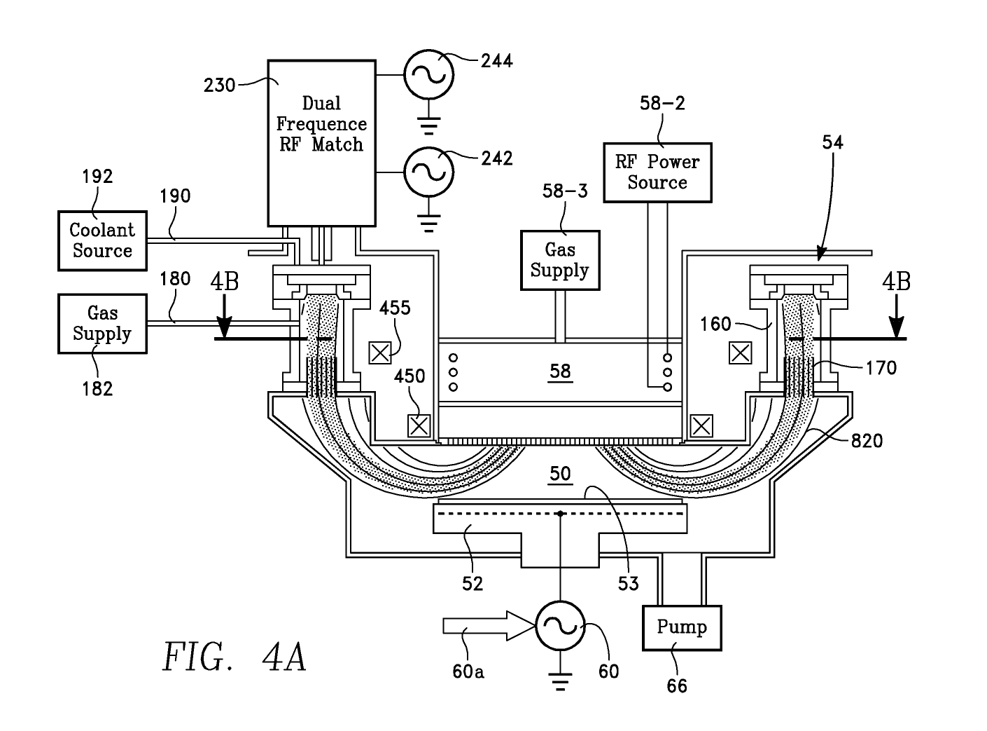

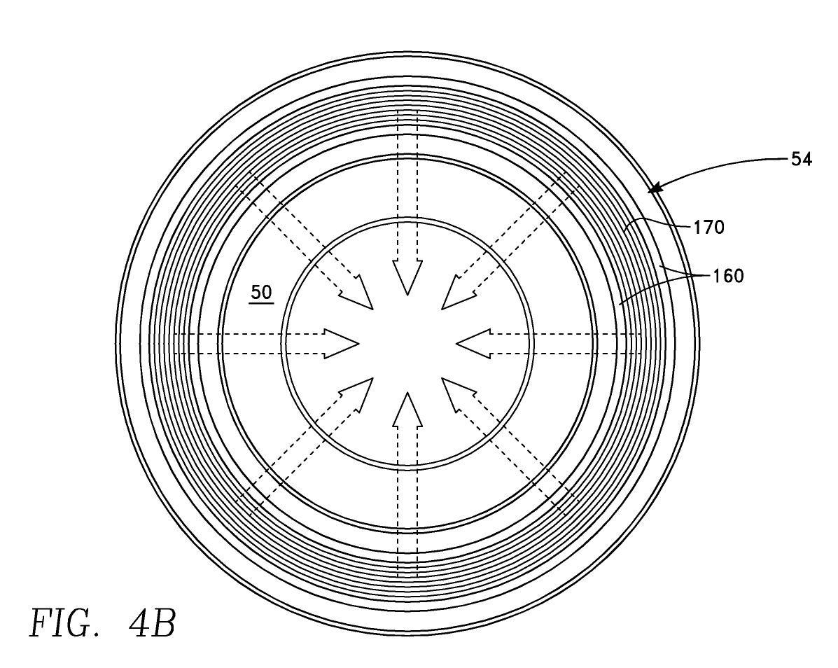

In a first embodiment (FIGS. 1A and 1B), an annular beam source has a tilted emission electrode surface, tilted walls and tilted grid apertures for angled beam injection. In a second embodiment (FIGS. 2A and 2B), four planar sources wider than the workpiece are installed at four sides of the chamber. The electron beam sources are tilted, as depicted. In further embodiments (FIGS. 3A and 4A), the electron beam is tilted relative to the workpiece by magnetic fields, with the remote plasma source shielded from them by magnetic shields.

In one embodiment, the remote plasma source can be an inductively-coupled plasma discharge with RF coils coaxial with the chamber body, and its operation can be very sensitive to the presence of external magnetic fields.

### Mechanically Tilted Radial Electron Beam Source:

FIGS. 1A and 1B depict an embodiment of a plasma reactor having a cylindrical processing chamber 50 including an electrostatic chuck 52 holding a workpiece 53, a circularly distributed electron beam (e-beam) source 54 for creating a radical-poor, low-electron temperature (Te) plasma in the processing chamber 50, a remote plasma source 58 for producing and supplying radicals through an outlet 58a to plasma in the processing chamber 50, and a bias power generator 60 for creating a voltage drop (with fine control in 0-50 V range) between the workpiece 53 and the plasma to accelerate ions above etch-threshold energies. In one embodiment, the remote plasma source 58 includes a plasma source power applicator 58-1 (such as a coil antenna) driven by an RF power source 58-2, and a gas source 58-3 coupled to the interior of the remote plasma source 58. The outlet 58a of the remote plasma source 58 includes a showerhead 90 that functions as an ion-blocking grid. The showerhead 90 blocks ions but admits radicals or neutrals, and may be referred to as a remote plasma source grid. A beam outlet 54a of the e-beam source 54 is covered by a filtering grid 170, which is an e-beam source filter grid that admits low temperature electrons forming the electron beam but blocks ions and other plasma by-products produced within the e-beam source 54.

The control input 59 of the remote plasma source 58 may be implemented in various ways. For example, the control input 59 may control the power level of an RF generator 58-2 driving a plasma source power applicator 58-1 in the remote plasma source 58. As another possibility, the control input 59 may control a valve at the outlet 58a between the remote plasma source 58 and the processing chamber 50.

The bias power generator 60 may have a bias voltage control input 60a that provides the fine control in a 0-50 V range. In one embodiment, the range is 0-25V. The electron beam source 54 includes a beam control input 62 that controls the electron energy of the electron beam source 54. The control input 62 may control the output power level of one of the RF generators 242, 244.

The remote plasma source 58 may have a control input 59 for controlling the rate at which the remote plasma source 58 supplies radicals into the processing chamber 50. The control input 59 is independent of the beam control input 62. The rate at which the remote plasma source 58 supplies radicals into the processing chamber 50 and the energy of the electron beam thus are controlled independently of one another. A vacuum pump 66 may be provided for evacuating the processing chamber 50.

In one embodiment, the circularly distributed radial electron beam plasma source 54 includes a circular (e.g., ring-shaped) emitting electrode 110 mounted on a backing plate 120. The backing plate 120 is mounted on a chill plate 130. A ceramic spacer 140 and an insulator 150 hold the cylindrical emitting electrode 110 in place relative to an electron gun body 160. The electron gun body 160 may be circular and formed of an electrically conductive material and be connected to a return potential or to ground. In the illustrated embodiment, the electron gun body 160 extends radially along an e-beam propagation path P and has a beam outlet opening 160a at a distal end opposite the emitting electrode 110. The electron gun body 160 is tilted so that the e-beam propagation path P lies at a small angle A (e.g., 10 to 20 degrees) relative to the workpiece 53 and tilts upwardly toward the axis of symmetry. The electron beam is therefore distributed in a conical shape having an apex coinciding with the axis of symmetry of the cylindrical processing chamber 50.

The filtering grid 170 is positioned within the beam outlet opening 160a. A backfill gas feed 180 conducts gas suitable as an electron source (e.g., Argon) from a gas supply 182 into the interior of the electron gun body 160. A coolant feed or conduit 190 conducts coolant from a coolant source 192 to the chill plate 130. An RF feed 200 conducts RF power to the emitting electrode 110 through the chill plate 130 and through the backing plate 120. An insulator 210 surrounds a portion of the RF feed 200. The electron gun body 160, the emitting electrode 110, the backing plate 120, the chill plate 130, the ceramic spacer 140, the insulator 150 and the RF feed 200 together form a circularly distributed e-beam source assembly 212, which may be contained within a circularly distributed RF shield enclosure 220. The RF feed 200 receives RF power through a dual frequency impedance match 230 from RF power generators 242 and 244. In one embodiment, the RF power generator 242 produces low frequency RF power and the RF power generator 244 produces high frequency RF power.

An RF plasma discharge is ignited between the emitting electrode 110 and the electron gun body 160 that serves as an RF return. Two RF frequencies can be supplied by the RF power generators 242, 244 including a low frequency such as 2 MHz, and a HF or VHF frequency such as 60 MHz. This provides independent control over: (1) the density of plasma (controlled by the level of the HF or VHF power), which determines the density of the beam electrons, and (2) the DC self-bias at the emitting electrode 110 (controlled by the level of the low frequency power), which determines the energy of the beam electrons. Generally, the energy of the beam electrons may be controlled by controlling the output power level of the low frequency bias power generator 242. Independent control over beam electron density can also be achieved by adding an inductively coupled plasma source to the e-beam source assembly 212.

Because the area of the electron gun body 160 is larger than the area of the emitting electrode 110, the RF-induced DC self-bias will be much larger at the smaller emitting electrode 110, and can reach a level appropriate for the electron beam technology.

A significant portion of the applied RF power is deposited into the emitting electrode 110 in the form of heat, due to constant bombardment by high-energy ions. The chiller plate 130 has non-conductive cooling fluid running through it, and is coupled through the backing plate 120 to the emitting electrode 110. The RF feed 200 is coupled through the chill plate 130 and the backing plate 120 to the emitting electrode 110. The backing plate 120 serves as an RF plate distributing applied RF power evenly over the emitting electrode 110.

The filtering grid 170 has high aspect ratio (elongate) openings 170a and prevents leakage of the RF plasma ions and radicals created inside the electron gun body 160 into the process chamber 50. In the illustrated embodiment, the high aspect ratio openings 170a are parallel with the direction of the electron beam propagation path P.

Further, the chemically aggressive process gas inside the process chamber 260 is blocked from entering the interior of the electron gun body 160. This gas separation is achieved using the back fill gas feed 180 by backfilling the interior of the electron gun body 160 with inert gas such as Argon, supplied at a sufficiently high flow rate to create a considerable gas pressure drop (for example, about 30 mT) across the filtering grid 170. In turn, high-energy electrons can go through the high aspect ratio openings of the filtering grid 170, due to high directionality of their velocity distribution.

### Multiple Linear Tilted Radial Electron Beam Sources:

FIGS. 2A and 2B depict an embodiment in which four similar or identical electron beam sources 54-1, 54-2, 54-3 and 54-4 are spaced apart at equal angles facing the axis of symmetry. In the illustrated embodiment, each of the electron beam sources 54-1, 54-2, 54-3 and 54-4 is planar (non-circular) and provides a linear electron beam. Each of the electron beam sources 54-1, 54-2, 54-3 and 54-4 is tilted upwardly (i.e., toward the remote plasma source 58) at a slight angle A. The four electron beam sources 54-1, 54-2, 54-3 and 54-4 are disposed at successive right angles. Each one of the four electron beam sources 54-1, 54-2, 54-3 and 54-4 includes elements corresponding to the elements of the electron beam source 54 of FIG. 1A. Such corresponding elements include a tilted e-beam gun body 160-1, 160-2, 160-3 and 160-4, respectively, which corresponds to the e-beam gun body of FIG. 1A. Each of the four e-beam gun bodies 160-1, 160-2, 160-3 and 160-4 of FIG. 2A is linear or straight, while the e-beam gun body 160 of FIG. 1A is circularly distributed. A number of electron beam sources other than four may be employed in alternative embodiments, the angular separation between them being in accordance with the number of electron beam sources. The embodiment of FIGS. 2A and 2B provide four-fold symmetry in plasma distribution.

Radial Electron Beam Source with Magnetic Tilting:

FIGS. 3A and 3B depict a modification of the embodiment of FIG. 1A, in which the electron beam source 54 does not need to be tilted in order to tilt the electron beam. Instead, the beam path P is tilted by a magnet 400 (e.g., an electromagnet) adjacent the beam outlet 160a. The magnet 400 has curved magnetic field lines 810 which are generally followed by the electron beam path P. The electron beam source 54 may be oriented in an untilted radial direction, as depicted in FIG. 3A. A magnetic shield 405 in the shape of a partial cylinder coaxial with the chamber 50 is positioned between the magnet 400 and the remote plasma source 58. If the magnet 400 is an electromagnet or coil, the degree of tilting of the electron beam is controlled by the electric current supplied to the electromagnet.

Axial Electron Beam Source with Magnetic Tilting:

FIGS. 4A and 4B depict a modification of the embodiment of FIG. 1A, in which the electron beam source 54 faces downwardly in an axial direction and emits a cylindrical electron beam along the axial direction. A pair of ring-shaped magnets 450, 455 produce curved magnetic field lines 820 which are generally followed by the electron beam path P, thereby providing the desired tilting. If either or both the magnets 450, 455 is an electromagnet or coil, the degree of tilting of the electron beam is controlled by the electric current supplied to the electromagnet. The electron beam source 54 may be oriented in an untilted radial direction, as depicted in FIG. 3A.

### Opposing Linear Radial Electron Beam Sources:

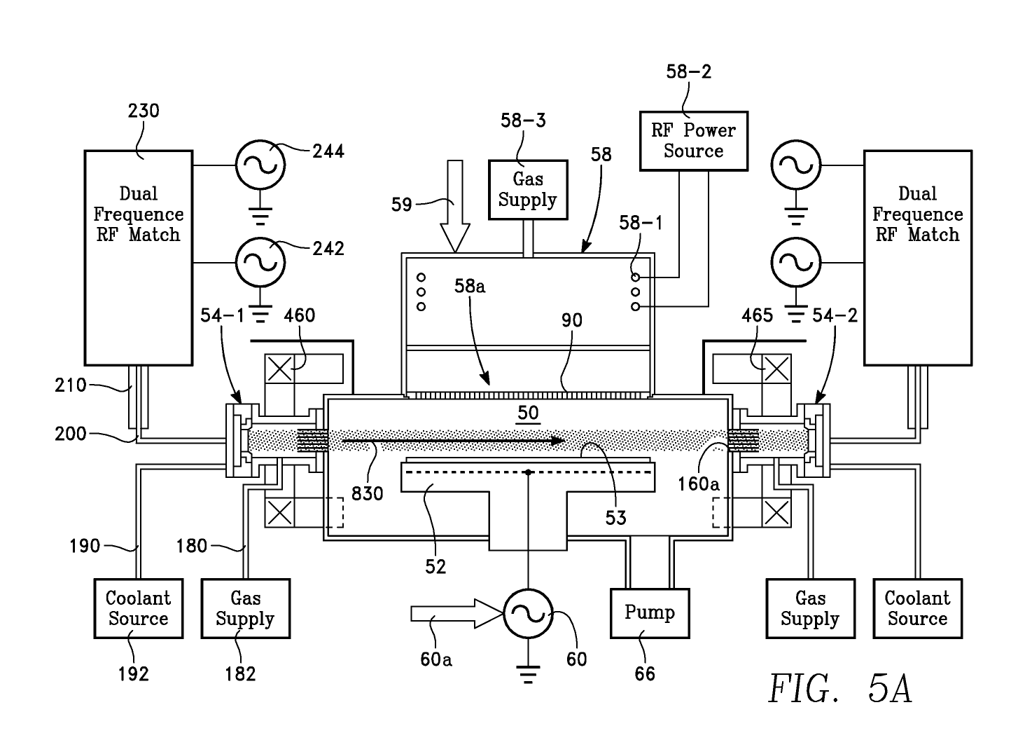

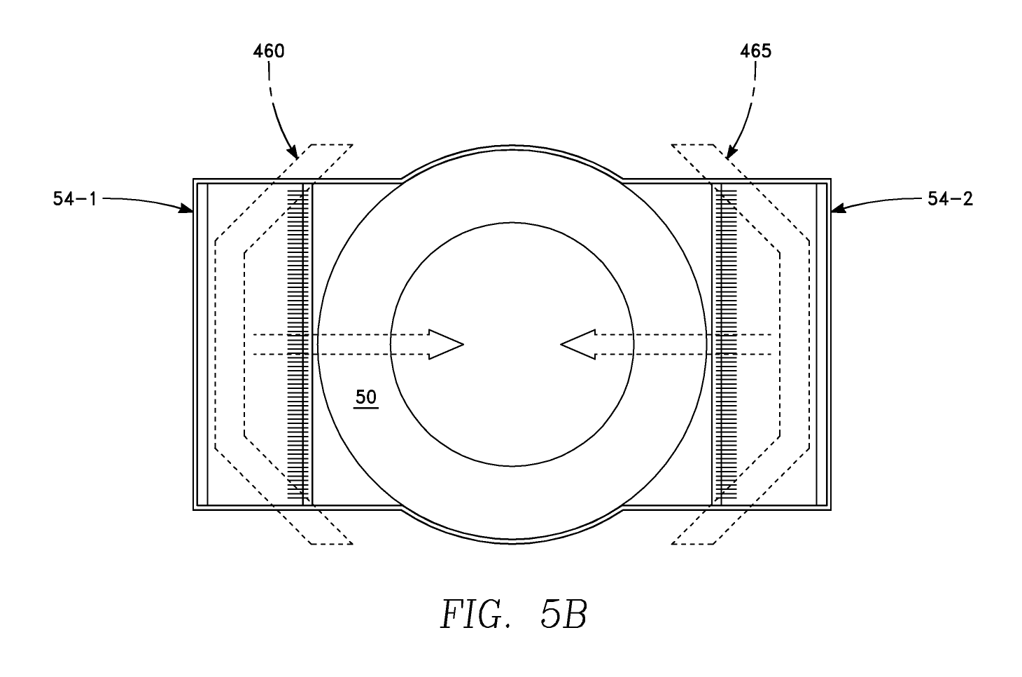

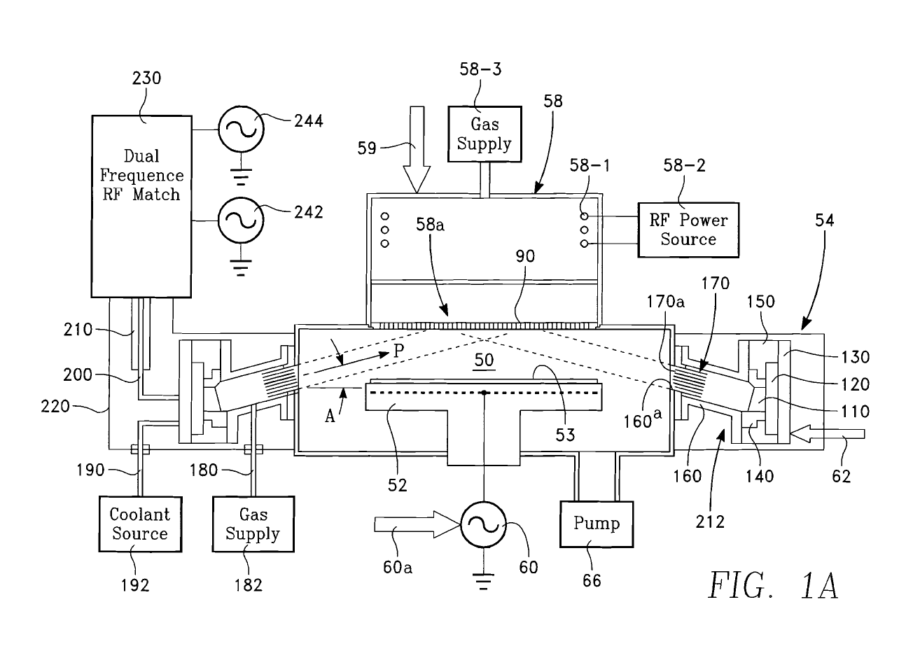

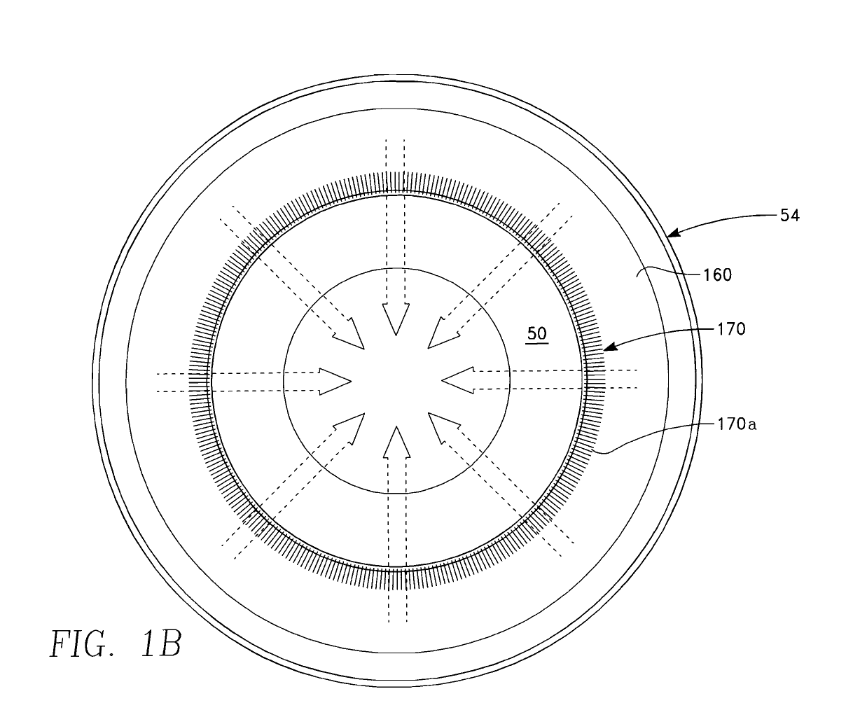

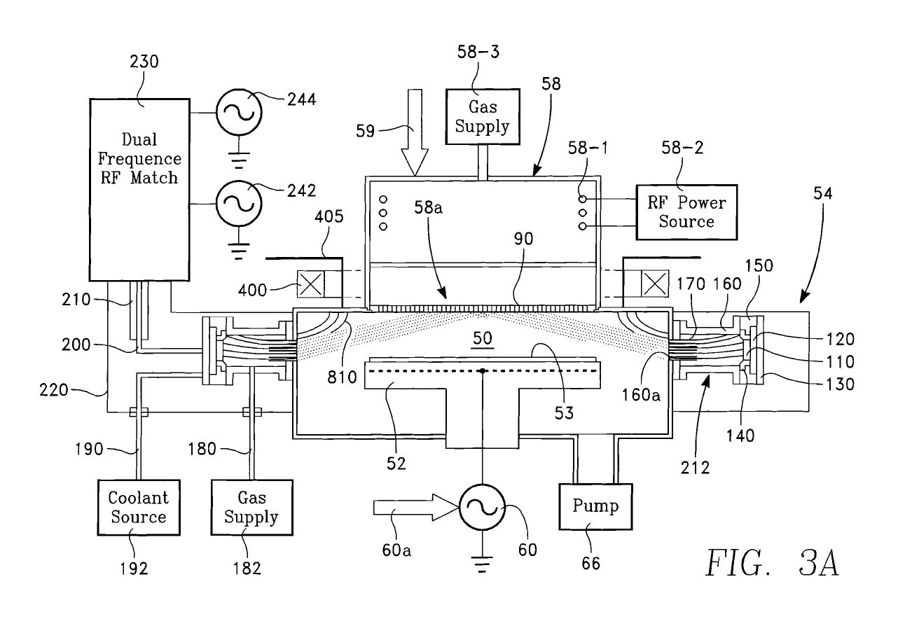

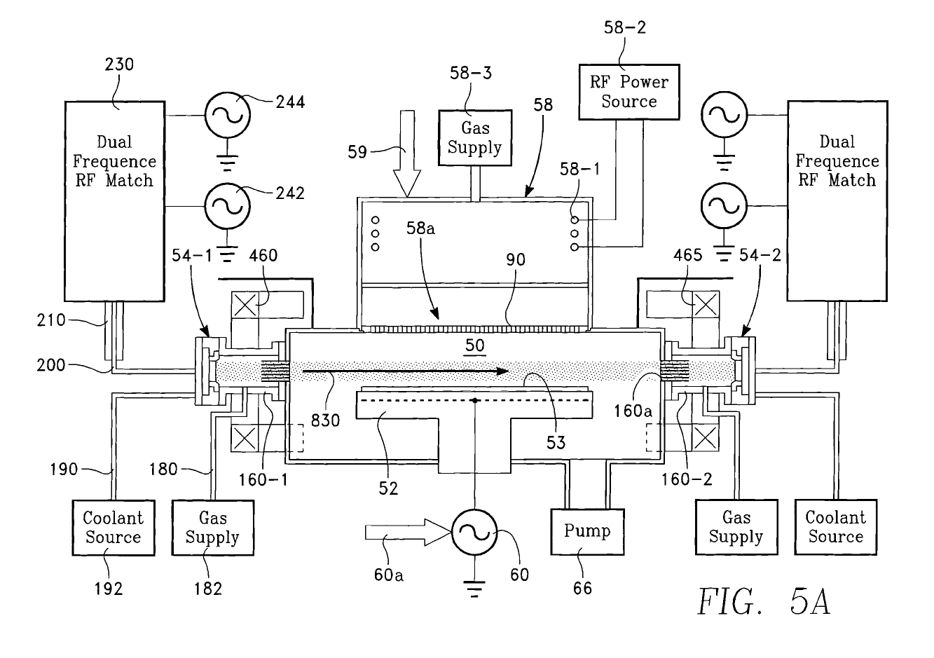

FIGS. 5A and 5B depict an embodiment in which two identical electron beam sources 54-1 and 54-are spaced apart at a 180 degree angle facing the axis of symmetry. Each of the electron beam sources 54-1, 54-2 is planar (non-circular) and provides a linear electron beam. Each one of the two electron beam sources 54-1, 54-2 includes elements corresponding to the elements of the electron beam source 54 of FIG. 1A. Such corresponding elements include e-beam gun bodies 160-1, 160-2, respectively, which are each similar to the single e-beam gun body of FIG. 1A. Each of the e-beam gun bodies 160-1, 160-2 of FIG. 5A is linear or straight. Referring to FIG. 5A, a pair of opposing magnets 460 and 465 are placed adjacent to the electron beam sources 54-1, 54-2 respectively. The pair of magnets 450, 455 face one another along opposite directions and produce straight magnetic field lines 830 followed by the electron beam path.

While the foregoing is directed to embodiments of the present invention, other and further embodiments of the invention may be devised without departing from the basic scope thereof, and the scope thereof is determined by the claims that follow.

What is claimed is:

1. A plasma reactor comprising:
a processing chamber having a ceiling, a cylindrical side wall, a circumferential opening through said side wall and an axis of symmetry;
a workpiece support in facing said ceiling;
an electron beam source comprising:
a circularly distributed electron gun body surrounding said side wall and having an electron beam emission port coinciding with said circumferential opening and defining an electron beam path;
a circularly distributed e-beam source filter grid in said electron beam emission port comprising plural elongate apertures parallel with said electron beam path, said electron gun body and said plural elongate apertures being tilted through a tilt angle relative to a radius of said axis of symmetry whereby said electron beam path is tilted in a direction away from said workpiece support;
a remote plasma source comprising a remote chamber overlying said ceiling and having an outlet facing said processing chamber, and a filtering grid covering said outlet.

2. The plasma reactor of claim 1 wherein said electron beam source further comprises:
an emission electrode near an end of said electron gun body opposite said electron beam emission port;
an RF power feed conductor having an interior end coupled to said emission electrode and an external end for receiving RF plasma source power.

3. The plasma reactor of claim 2 wherein said emission electrode is tilted through said tilt angle.

4. The plasma reactor of claim 1 wherein said processing chamber, said e-beam source filter grid, said electron gun body, said outlet and said workpiece support are coaxial.

5. The plasma reactor of claim 1 further comprising an RF bias power source coupled to said workpiece support.

6. The plasma reactor of claim 2 further comprising first and second plasma RF source power supplies coupled to said external end of said RF power feed.

7. The plasma reactor of claim 1 wherein said e-beam source filter grid comprises apertures of a first length and a first opening size, and said filtering grid comprises apertures of a second length and a second opening size, said first length exceeding said second length and said first opening size exceeding said second opening size.

8. The plasma reactor of claim 1 wherein said remote plasma source comprise a gas supply feed, a plasma source power applicator and a plasma source power supply coupled to said plasma source power applicator.

9. The plasma reactor of claim 8 further comprising a radical production control governing said plasma source power supply.

10. The plasma reactor of claim 6 further comprising an electron beam source controller coupled to one of said first and second plasma RF source power supplies.

11. A plasma reactor comprising:
a processing chamber having a ceiling and an axis of symmetry;
a workpiece support in facing said ceiling;
and array of electron beam sources each having a respective electron beam path toward said axis of symmetry, each one of said electron beam sources comprising:
an electron gun body surrounding said processing chamber and having an electron beam emission port coinciding with the respective electron beam path;
an e-beam source filter grid in said electron beam emission port comprising plural elongate apertures parallel with the respective electron beam path, said electron gun body and said plural elongate apertures being tilted through a tilt angle relative to a radius of said axis of symmetry whereby the respective electron beam path is tilted in a direction away from said workpiece support;
a remote plasma source comprising a remote chamber overlying said ceiling and having an outlet facing said processing chamber, and a filtering grid covering said outlet.

12. The plasma reactor of claim 11 wherein each of said electron beam sources further comprises:
an emission electrode near an end of said electron gun body opposite said electron beam emission port;
an RF power feed conductor having an interior end coupled to said emission electrode and an external end for receiving RF plasma source power.

13. The plasma reactor of claim 12 wherein said emission electrode is tilted through said tilt angle.

14. The plasma reactor of claim 11 further comprising an RF bias power source coupled to said workpiece support.

15. A plasma reactor comprising:
a processing chamber having a ceiling, a cylindrical side wall, a circumferential opening through said side wall and an axis of symmetry;
a workpiece support facing said ceiling;
an electron beam source comprising:
a circularly distributed electron gun body surrounding said side wall and having an electron beam emission port coinciding with said circumferential opening;
a circularly distributed e-beam source filter grid in said electron beam emission port;
a magnet adjacent said electron gun body for diverting an electron beam flowing through said electron beam emission port to an electron beam path that is tilted away from a plane of said workpiece support through a tilt angle; and
a remote plasma source comprising a remote chamber overlying said ceiling and having an outlet facing said processing chamber, and a filtering grid covering said outlet.

16. The plasma reactor of claim 15 wherein said electron beam source is axial and emits electrons in an axial direction.

17. The plasma reactor of claim 15 wherein said electron beam source is radial and emits electrons in a radial direction.

18. The plasma reactor of claim 1 wherein said electron beam source further comprises:
an emission electrode near an end of said electron gun body opposite said electron beam emission port;
an RF power feed conductor having an interior end coupled to said emission electrode and an external end for receiving RF plasma source power.

19. The plasma reactor of claim 18 wherein said emission electrode is tilted through said tilt angle.

20. The plasma reactor of claim 15 wherein said processing chamber, said e-beam source filter grid, said electron gun body, said outlet and said workpiece support are coaxial.
